(19) United States
(12) Patent Application Publication
(10) Pub. No.: US 2002/0092678 A1
(43) Pub. Date: Jul. 18, 2002

(54) Cable connector arrangement and method

(76) Inventors: Pasi Lehtonen, Kempele (FI); Jari Lapinlampi, Tupos (FI); Matti Lehto, Oulu (FI); Tero Saarenpaa, Kiiminki (FI); Arto Kuosmanen, Oulu (FI)

Correspondence Address: PILLSBURY WINTHROP, LLP, P.O. BOX 10500, MCLEAN, VA, 22102, US

(21) Appl. No.: 10/066,287

(22) Filed: Feb. 5, 2002

Related U.S. Application Data
(63) Continuation of application No. PCT/FI00/00670, filed on Aug. 4, 2000.

(30) Foreign Application Priority Data
Aug. 6, 1999 (FI) 19991685

(51) Int. Cl. H05K 1/16; H05K 3/30

(52) U.S. Cl. 174/268; 29/838; 29/832; 29/840; 174/260

(57) ABSTRACT

The invention relates to a method and an arrangement implementing the method for installing a connector and a cable, in which method the connector is fastened at its middle part with a fastening agent, the rest of the connector is fastened with fastening means and the cable is connected to the connector. Further, in the method, the middle part of the connector separate from the rest of the connector is fastened with a fastening agent, the rest of the connector is fastened to the cable, the cable is connected to the separate middle part of the connector, and the cable is fastened through the rest of the connector with fastening means.

This application is a Continuation of International Application PCT/FI00/00670 filed Aug. 4, 2000 which designated the U.S. and was published under PCT Article 21(2) in English.

### FIELD OF THE INVENTION

The invention relates to a method and arrangement for installing connectors and cables. Typically, the invention concerns installation of connectors and cables of a base station.

### BACKGROUND OF THE INVENTION

Connector structures used in RF technology are designed to fasten the cable to its fastening object, for instance a circuit board, and to transmit RF signals as desired between the cables and the fastening objects. In RF technology, the cables are typically coaxial cables. In a prior art arrangement, the connector structure is such that the centre pin, i.e. the middle part, of the connector is in the connector. The connector is fastened to the circuit board manually by soldering the middle part and with screws from the rest of the connector. A cable connector is fastened to the cable for connecting the cable to the connector on the circuit board. The prior art implementation is complex, which has a negative impact especially on material and time costs. Material costs are caused by the fact that two separate connector structures are needed: the connector fastened to the circuit board and the cable connector fastened to the cable. Time costs are caused by the complexity of installing the connectors and, through the connectors, the cable to the circuit board. Time costs arise especially from soldering the connector manually from its middle part to the circuit board, which is often slow. Unfastening the circuit board from the connectors is also very slow, because each manually soldered centre pin of the connector must be unfastened separately from the circuit board.

### BRIEF DESCRIPTION OF THE INVENTION

It is thus an object of the invention to implement a method and an apparatus implementing the method so as to solve the above-mentioned problems. This is achieved by a method of the invention for installing a connector and cable. In the method, the connector is fastened at its middle part with a fastening agent, other parts of the connector are fastened with fastening means and the cable is connected to the connector. The connector and the cable are installed in such a manner that the middle part of the connector separate from the rest of the connector is fastened with a fastening agent, the rest of the connector is fastened to the cable, the cable is connected to the separate middle part of the connector and the cable is fastened through the rest of the connector with the fastening means.

The invention also relates to an arrangement for installing a connector and a cable. The arrangement comprises the connector fastened at its middle part with a fastening agent and elsewhere with fastening means and the cable connected to the connector. The arrangement further comprises the middle part of the connector separate from the rest of the connector and fastened with a fastening agent, the rest of the connector fastened to the cable and the cable connected to the separate middle part of the connector and the cable fastened through the rest of the connector with the fastening means.

Preferred embodiments of the invention are disclosed in the dependent claims.

The invention is based on the fact that the middle part, i.e. centre pin, of the connector is a separate part from the rest of the connector, and it is soldered to a circuit board in an automated circuit-board manufacturing process, for instance. Further, the invention is based on the fact that the rest of the connector is fastened to the cable, which also functions as a grounding part. The cable is connected to the separate part of the connector fastened to the circuit board.

Significant savings in material and time costs are achieved by the method and arrangement of the invention. The simple structure of the connector structure makes material savings possible, which is very important especially with large production volumes. The connector implementation of the invention, in which the separate middle part of the connector can be fastened to a circuit board in an automated circuit-board manufacturing process, saves a great deal of time. Time-consuming manual soldering is thus no longer needed. Time saving is also achieved if the circuit board needs to be unfastened from the connectors. In the connector implementation of the invention, the separate middle part of the connector is a fixed part of the circuit board and there is no need for time-consuming desoldering when the circuit board is unfastened, as is the case in the prior art implementation.

### BRIEF DESCRIPTION OF THE FIGURES

In the following, the invention will be described by means of preferred embodiments and with reference to the attached drawings in which

FIGS. 1A to 1B show the structure of a coaxial cable,

FIGS. 2A to 2B show a first preferred embodiment of the invention,

FIGS. 3A to 3B show a second preferred embodiment of the invention.

### DESCRIPTION OF PREFERRED EMBODIMENTS

A lot of cabling is needed inside a base station. In connection with RF frequencies, the cables are usually coaxial cables. Cable connections are needed in a base station especially in connecting various modules to each other. A module comprises at least one circuit board and usually a casing in which one or more circuit boards reside. The modules can be separate detachable units in the base station. When modules are connected to each other with cables, the circuit boards of the modules are connected to each other. Cable connections can also be between circuit boards inside a module. Further, cable connections can be inside a circuit board in a module, for instance. The purpose of cable connections is to implement operational entities or to perform tests.

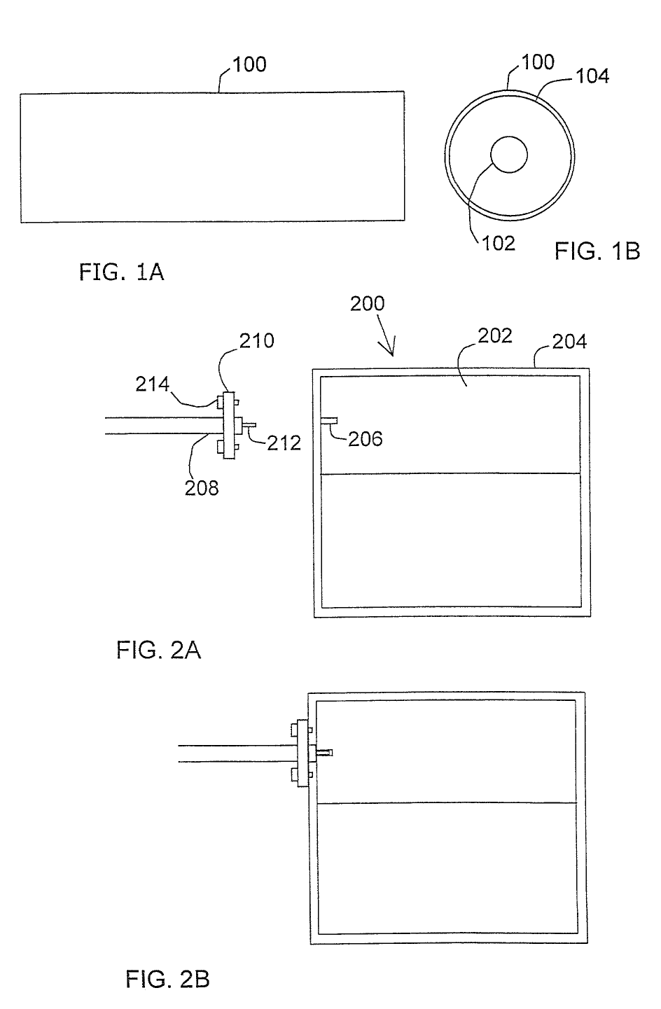

Connectors play quite an important role in the above-mentioned cable connections, their task is to connect the cable to the desired point in such a manner that the connection in question transmits the signals as desired. With RF frequencies, the connectors are RF connectors. The unwanted signal loss is minimised not only by means of a correct connector structure, but also by means of having the impedances of the cables and the connection points, i.e. circuit boards, for instance, arranged to match each other as well as possible. A typical characteristic impedance of a coaxial cable is 50 Ohm. FIGS. 1A to 1B show a typical structure of a coaxial cable, FIG. 1A in longitudinal direction and FIG. 1B in transverse direction. The outer layer of the coaxial cable is a sheath 100 which acts as a grounding element. The middle conductor 102 in FIG. 1B is the route of the desired signal. The insulator 104 in FIG. 1B insulates the middle conductor and the sheath so that the desired signal can be kept as pure as possible. The insulator is made of tetrafluoroethylene, for instance. The middle conductor 102 can be one uniform conductor or it can also be a multi-thread conductor bundle. Examples of different types of coaxial cables are semi-rigid, which has a rigid structure, and semi-flexible, which has a flexible structure.

The essential matter in the invention is that the middle part of the connector is separate from the rest of the connector and can be fastened to a circuit board in an automated circuit board manufacturing process like other components. The separate middle part of the connector can thus be considered a component of the circuit board. Paste, for instance tin paste, is typically used as the fastening agent. The automated circuit board manufacturing process is, for instance, as follows: a film with holes at the soldering points of the circuit board is placed on top of the circuit board; the circuit board is covered with paste, whereby the paste settles on the holes of the film, i.e. at the soldering points of the circuit board; the film is removed; the components are set on the circuit board in such a manner that the feet of the components are at the soldering points having paste; the circuit board is heated in a furnace to a temperature of +170° C., whereby the paste at the soldering points melt, and the circuit board is taken out of the furnace. When the temperature of the paste decreases, the paste solidifies, and the components fasten to the soldering points by means of the solidified paste.

FIGS. 2A to 2B show a first preferred embodiment of the invention, in which the arrangement and method of the invention is typically used in cable connections between the modules 200 of a base station in such a manner that the connector and the cable are installed on a circuit board 202 through a casing 204. There may be more than one circuit board in a module, and there may be several installation points for the connector and cable in one circuit board, which means that one module may comprise several installation points for the connector and cable. It is also possible to arrange other cable connections than those between base station modules. The connector and cable 208 is fastened to both the circuit board 202 and the casing 204. The separate middle part 206 of the connector is fastened to the circuit board to be placed in the module by means of a fastening agent. The above-mentioned fastening is typically performed in the same way as that of the rest of the components of the circuit board, for instance with the above-mentioned automated circuit board manufacturing process, in which the paste used in the manufacturing process is used as the fastening agent. A remaining part 210 of the connector is fastened to the end of the cable 208 by soldering or crimp-joining it to the sheath 100 of the cable. The remaining part of the connector is thus in contact with the grounding sheath, i.e. the remaining part of the connector is a grounding part. FIG. 2B shows a connector and cable installed on the circuit board 202 through the casing 204. If the middle conductor 102 of the cable is made of a uniform and rigid enough material, it can be used as a counter-piece 212 to the separate middle part 206 of the connector on the circuit board, which means that the separate middle part of the connector and the middle conductor of the cable can be connected to each other without an intermediate part. An intermediate part, i.e. a separate counter-piece, is fastened to the middle conductor, if the middle conductor is made of several threads or a quite flexible material or both. Even the above-mentioned fastening is usually done by soldering or as a crimp joint. This way, the cable can be connected with the counter-piece to the separate middle part of the connector on the circuit board. The joint between the counter-piece and the separate middle part of the connector is a contact joint which needs no fastening agent or means. After the above-mentioned joining, the remaining part of the connector is fastened with fastening means 214 through the casing 204 to the circuit board 202. The fastening means are typically screws. When the cable 208 needs to be unfastened from the circuit board 202 and casing 204, the fastening means, with which the remaining part of the connector is fastened to the casing, are opened and the cable is pulled away from the circuit board, i.e. the counter-piece is pulled away from the separate middle part of the connector. No solder joints need to be removed. Owing to the invention, unfastening the cables from the casing and circuit board is easy and fast.

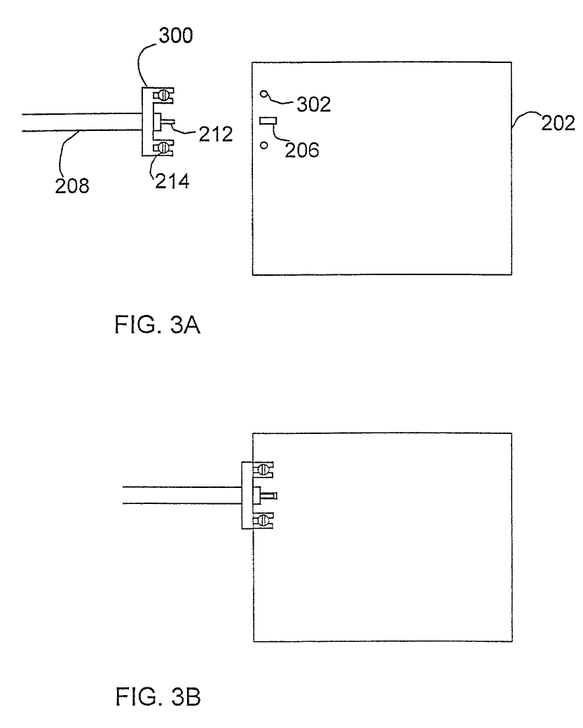

FIGS. 3A to 3B show a second preferred embodiment of the invention, in which the middle part 206 of the connector is similarly separate as in the first preferred embodiment of the invention, and the middle part 206 is fastened to the circuit board 202 as in the first preferred embodiment of the invention. In this embodiment, the connector and cable 208 are only fastened to the circuit board 202. A part 300 of the connector, as described in FIG. 3, for instance, is fastened to the end of the cable 208, which is fastened to the circuit board, the part 300 having the counter-piece 212 of the separate middle part 206 of the connector in the middle of the cable 208 end shown perpendicularly from the top and places for the fastening means 214 on the sides. The implementation alternatives of the counter-piece 212 in connection with various cable types are as described in the first preferred embodiment of the invention. The part 300 of the connector is a grounding part which is in contact with the grounding sheath 100 which is the outer layer of the cable. The part 300 of the connector is typically fastened to the end of the cable by soldering or crimp-joining. FIG. 3B shows how the cable 208 is connected with the counter-piece 212 to the separate middle part 206 of the connector fastened to the circuit board 202 and how the cable is at one end fastened through the part 300 of the connector with the fastening means 214 to the fastening objects 302 on the circuit board 202. The fastening means are screws, for instance. The above-mentioned fastening can also be implemented otherwise than with fastening means, for instance by soldering. It is possible to arrange cable connections inside a circuit board or between circuit boards by means of the second embodiment of the invention.

The first and second embodiment of the invention can, if necessary, be implemented in one and the same cable. The first end of the cable can then be installed on the circuit board using the first preferred embodiment of the invention and correspondingly, the second end of the cable can be installed on the circuit board using the second preferred embodiment of the invention. If there are more than two cable ends, either of the preferred embodiments of the invention can be used in each of them as necessary.

Cable fastenings need, for instance, to be unfastened in a base station when repair and alteration work are done. The different embodiments of the invention provide an easy and fast unfastening of cables and connectors and correspondingly, fastening mainly due to the fact that solder joints need not be removed or re-soldered.

In addition to implementing operational entities, quite an important function of cable connections is various kinds of tests in which signals are transmitted over cables between test equipment and parts being tested. For instance, internal testing of a circuit board or an inter-circuit board testing can be considerably improved owing to the invention in various embodiments of the invention, because the cables used in testing can quickly be connected to the desired testing points to which the separate middle part of the connector has already been fastened in an automated manufacturing process, for instance. Correspondingly, the unfastening of the cables used in testing from the testing points is easy. In some tests, it is not even necessary to fasten the remaining part of the connector to the casing or circuit part, but it is enough to connect the counter-piece and the separate middle part of the connector to each other for the test.

Even though the invention has above been described with reference to the examples in the attached figures, it is obvious that the invention is not restricted to them, but can be modified in many ways within the scope of the inventive idea described in the attached claims. For instance, the terms ‘separate middle part 206 of the connector’ and ‘middle conductor 102’ are names given on the basis of a typical cable structure and said parts need not necessarily be in the middle of the connector or cable structure. The invention is also not restricted in any way to a base station only, but can be utilised in quite different locations where connectors and cables are needed.

1. A method of installing a connector and a cable, comprising
fastening a middle part of the connector separate from the rest of the connector with a fastening agent,
fastening the rest of the connector to the cable,
connecting the cable to the separate middle part of the connector,
fastening the cable through the rest of the connector with fastening means.

2. A method as claimed in claim 1, where in the parts of the connector and the cable through the connector parts are fastened to at least one fastening object.

3. A method as claimed in claim 2, where in the separate middle part of the connector is fastened to a first fastening object and the cable is fastened through the rest of the connector to a second fastening object.

4. A method as claimed in claim 2, where in the fastening object is a circuit board.

5. A method as claimed in claim 2, where in the fastening object is a casing.

6. A method as claimed in claim 4, where in at least one middle part of the connector separate from the rest of the connector is fastened to the circuit board in an automated circuit board manufacturing process.

7. A method as claimed in claim 1, where in the rest of the connector is soldered to the cable.

8. A method as claimed in claim 1, where in the rest of the connector is fastened to the cable by crimping.

9. A method as claimed in claim 1, where in the rest of the connector is a grounding part.

10. A method as claimed in claim 1, where in the cable is connected by a counter-piece to the separate middle part of the connector.

11. A method as claimed in claim 1, where in the connector is an RF connector.

12. An arrangement for installing a connector and a cable, which arrangement comprises a connector fastened at its middle part with a fastening agent and with fastening means from the rest of the connector, and a cable connected to the connector, where in the arrangement comprises:
a middle part of the connector separate from the rest of the connector and fastened with a fastening agent,
the rest of the connector fastened to a cable,
the cable connected to the separate middle part of the connector and the cable fastened through the rest of the connector with fastening means.

13. An arrangement as claimed in claim 12, where in the arrangement comprises fastenings of the connector parts and the cable to at least one fastening object, the cable being fastened to said at least one fastening object through the connector parts.

14. An arrangement as claimed in claim 13, where in the arrangement comprises fastening the separate middle part of the connector to a first fastening object and fastening the cable through the rest of the connector to a second fastening object.

15. An arrangement as claimed in claim 13, where in the arrangement comprises a circuit board as the fastening object.

16. An arrangement as claimed in claim 13, where in the arrangement comprises a casing as the fastening object.

17. An arrangement as claimed in claim 15, where in the arrangement comprises at least one middle part of the connector separate from the rest of the connector and fastened to a circuit board in an automated circuit board manufacturing process.

18. An arrangement as claimed in claim 12, where in the arrangement comprises the rest of the connector fastened to the cable by soldering.

19. An arrangement as claimed in claim 12, where in the arrangement comprises the rest of the connector fastened to the cable by crimping.

20. An arrangement as claimed in claim 12, where in the arrangement comprises a grounding part as the rest of the connector.

21. An arrangement as claimed in claim 12, where in the arrangement comprises the cable connected by a counter-piece to the separate middle part of the connector.

22. An arrangement as claimed in claim 12, where in the arrangement comprises an RF connector as the connector.
